(19) United States
(12) Patent Application Publication
(10) Pub. No.: US 2025/0021823 A1
(43) Pub. Date: Jan. 16, 2025

(54) ADAPTIVE DRIVING MODEL FOR VIRTUAL TEST DRIVING INCLUDING ABSTRACT ACTIONS

(71) Applicant: TOYOTA RESEARCH INSTITUTE, INC., LOS ALTOS, CA (US)

(72) Inventors: JOHN SUBOSITS, Mountain View, CA (US); YUN JUNG LEE, Mountain View, CA (US); SHAWN MANUEL, Mountain View, CA (US)

(73) Assignees: TOYOTA RESEARCH INSTITUTE, INC., LOS ALTOS, CA (US); TOYOTA JIDOSHA KABUSHIKI KAISHA, TOYOTA-SHI (JP)

(21) Appl. No.: 18/349,845

(22) Filed: Jul. 10, 2023

(51) Int. Cl. G06N 3/092; G06F 30/27

(52) U.S. Cl. CPC G06N 3/092; G06F 30/27

(57) ABSTRACT

Systems and methods are provided for evaluating different vehicle and race configurations in simulation through deriving a driving model that can accurately account for driver preferences, environment settings and changes in vehicle setup without using independent models. The driving model may be used to simulate race scenarios to determine optimal vehicle setup parameters, optimal goals and optimal functions to be implemented on a vehicle during a race. The systems and methods may include generating goals according to training data; determining functions to achieve the goals based on algorithms; training a driving model based on the training data, the goals and the functions; performing one or more simulations of a set of goals and a set of functions derived from the driving model based on first race characteristics; and generating results comprising an optimal vehicle setup, optimal goals and optimal functions according to the simulations.

### TECHNICAL FIELD

The present disclosure relates generally to modeling driver control, and more particularly, some embodiments relate to driver simulation modeling to assist driver training and vehicle setup parameter testing.

### DESCRIPTION OF RELATED ART

The development of algorithms and architectures for autonomous racing is a growing research field. With the development and implementation of test platforms and modeling approaches in traditional motorsports, autonomous motorsports research has matured sufficiently to provide new insights to the practice of traditional motorsports. One avenue of providing new insights is through simulation-based development. Establishing control algorithms that can drive as well as, and in the same style as, professional drivers may greatly increase the number of possibilities that can be tested in simulation as the control algorithms may be used as a surrogate for professional drivers during vehicle development and tuning processes.

However, such control algorithms may need to be implemented with realistic factors, such as driving at friction limits, which may be difficult to characterize a priori. This is particularly true when factors may vary in response to changes in vehicle design and setup. To tease out subtle differences in performance between vehicle configurations, vehicle control algorithms may have to determine functions for various vehicle configurations in order to demonstrate the same adaptive behaviors to changes in a vehicle's handling as a professional driver.

In the context of vehicle setup optimization for racing, adaptive behaviors may include adjustments to changes in “grip” and “balance.” Grip refers to the overall performance potential of a vehicle based on the coefficient of friction between the surface of a racetrack and the surface of a tire of the vehicle. The grip may be used to determine a vehicle's ability to accelerate, brake, and turn corners (“cornering”) on a racetrack. A vehicle limited by the grip available from its front axle may be considered as understeering. A vehicle limited by the grip available from its rear axle may be considered as oversteering. Balance refers to the relative ability of the front and rear axles of a vehicle to generate cornering force during cornering. The cornering force is a measurement of the force exerted on the vehicle's center of gravity. The balance of a vehicle may change throughout a racetrack, both at corners and between corners. A well-tuned vehicle may offer superior grip to support achieving fast laps on the racetrack, while maintaining an overall balance of the vehicle throughout the racetrack for multiple laps.

However, determining the parameters and the method of driving a vehicle to achieve the best grip and balance for a long duration of a race proves to be difficult when characteristics of different drivers, along with changes in vehicle configurations, may influence the selection of parameters, along with the performance, of the vehicle during a race.

### BRIEF SUMMARY OF THE DISCLOSURE

According to various embodiments of the disclosed technology, systems and methods for determining optimal parameters and performance functions of a vehicle to achieve higher level goals on a racetrack are provided.

In accordance with some embodiments, a method for virtual test driving using a hierarchical reinforcement learning approach is provided. The method comprises: receiving training data associated with characteristics regarding a race; generating one or more higher level goals according to the training data; determining one or more lower level functions of a vehicle to achieve the one or more higher level goals based on control algorithms; training a driving model based on the training data, the one or more higher level goals and the one or more lower level functions; performing one or more simulations of a set of higher level goals and a set of lower level functions derived from the driving model based on first race characteristics; and generating results comprising an optimal vehicle setup, optimal goals and optimal functions according to the one or more simulations.

In some embodiments, the received training data comprises vehicle setup data, driver data and environment data.

In some embodiments, the vehicle is a race car.

In some embodiments, the vehicle setup data comprises a mechanical and electrical setting of the vehicle.

In some embodiments, the driver data comprises a driver performance characteristic.

In some embodiments, the environment data comprises a racetrack layout, conditions of a racetrack and weather settings.

In some embodiments, the generated one or more higher level goals comprises a selection of an apex point, a braking point and an acceleration point.

In some embodiments, the determined one or more lower level functions comprises an action to be performed with the vehicle while the vehicle is in motion.

In some embodiments, the first race characteristics comprise at least one of a first vehicle setup, a first driver data or a first environment data.

In some embodiments, the method further comprises displaying the generated results on a Graphical User Interface (GUI).

In some embodiments, the method further comprises: performing a second simulation of the results; and displaying the second simulation of the results on a GUI.

In some embodiments, the method further comprises: generating an adaptive controller that adapts to changes in race characteristics; generating second results of at least one of a second optimal vehicle setup, second optimal goals or second optimal functions according to the driving model and second race characteristics; and displaying the second results on a GUI.

In another aspect, a system for virtual test driving using a hierarchical reinforcement learning approach is provided that comprises one or more processors; and memory coupled to the one or more processors to store instructions, which when executed by the one or more processors, cause the one or more processors to perform operations. The operations may include: receiving training data associated with characteristics regarding a race; generating one or more higher level goals according to the training data; determining one or more lower level functions of a vehicle to achieve the one or more higher level goals based on control algorithms; training a driving model based on the training data, the one or more higher level goals and the one or more lower level functions; receiving first race characteristics indicative of characteristics of a first race; deriving a first set of higher level goals and a first set of lower level functions of the vehicle based on the first race characteristics, wherein the first set of higher level goals and the first set of lower level functions are derived from the driving model; performing one or more simulations of the first set of higher level goals and the first set of lower level functions based on the first race characteristics; and generating results comprising an optimal vehicle setup, optimal goals and optimal functions according to the one or more simulations.

In some embodiments, the received training data comprises vehicle setup data, driver data and environment data.

In some embodiments, the vehicle is a race car.

In some embodiments, the vehicle setup data comprises a mechanical and electrical setting of the vehicle.

In some embodiments, the driver data comprises a driver performance characteristic.

In some embodiments, the environment data comprises a racetrack layout, conditions of a racetrack and weather settings.

In some embodiments, the generated one or more higher level goals comprises a selection of an apex point, a braking point and an acceleration point.

In some embodiments, the determined one or more lower level functions comprises an action to be performed with the vehicle while the vehicle is in motion.

In some embodiments, the received first race characteristics comprises at least one of a first vehicle setup, a first driver data or a first environment data.

In some embodiments, the system further comprises operations comprising displaying the generated results on a Graphical User Interface (GUI).

In some embodiments, the system further comprises operations comprising: performing a second simulation of the results; and displaying the second simulation of the results on a GUI.

In some embodiments, the system further comprises operations comprising: generating an adaptive controller that adapts to changes in race characteristics; generating second results of at least one of a second optimal vehicle setup, second optimal goals or second optimal functions according to the driving model and second race characteristics; and displaying the second results on a GUI.

In another aspect, a non-transitory machine-readable medium is provided. The non-transitory computer-readable medium includes instructions that when executed by a processor cause the processor to perform operations including: receiving training data associated with characteristics regarding a race; generating one or more higher level goals according to the training data; determining one or more lower level functions of a vehicle to achieve the one or more higher level goals based on control algorithms; training a driving model based on the training data, the one or more higher level goals and the one or more lower level functions; receiving first race characteristics indicative of characteristics of a first race; deriving a first set of higher level goals and a first set of lower level functions of the vehicle based on the first race characteristics, wherein the first set of higher level goals and the first set of lower level functions are derived from the driving model; performing one or more simulations of the first set of higher level goals and the first set of lower level functions based on the first race characteristics; and generating results comprising an optimal vehicle setup, optimal goals and optimal functions according to the one or more simulations.

In some embodiments, the received training data comprises vehicle setup data, driver data and environment data.

In some embodiments, the vehicle is a race car.

In some embodiments, the vehicle setup data comprises a mechanical and electrical setting of the vehicle.

In some embodiments, the driver data comprises a driver performance characteristic.

In some embodiments, the environment data comprises a racetrack layout, conditions of a racetrack and weather settings.

In some embodiments, the generated one or more higher level goals comprises a selection of an apex point, a braking point and an acceleration point.

In some embodiments, the determined one or more lower level functions comprises an action to be performed with the vehicle while the vehicle is in motion.

In some embodiments, the received race characteristics comprises at least one of a first vehicle setup, a first driver data or a first environment data.

In some embodiments, the non-transitory machine-readable medium further comprises operations comprising displaying the generated results on a Graphical User Interface (GUI).

In some embodiments, the non-transitory machine-readable medium further comprises operations comprising: performing a second simulation of the results; and displaying the second simulation of the results on a GUI.

In some embodiments, the non-transitory machine-readable medium further comprises operations comprising: generating an adaptive controller that adapts to changes in race characteristics; generating second results of at least one of a second optimal vehicle setup, second optimal goals or second optimal functions according to the driving model and second race characteristics; and displaying the second results on a GUI.

Other features and aspects of the disclosed technology will become apparent from the following detailed description, taken in conjunction with the accompanying drawings, which illustrate, by way of example, the features in accordance with embodiments of the disclosed technology. The summary is not intended to limit the scope of any inventions described herein, which are defined solely by the claims attached hereto.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 is an example illustration of a computing system that performs driver simulation modeling to assist driver training and vehicle setup parameter testing, according to example embodiments described in the present disclosure.

FIG. 2 is an example illustration of a schematic of a Neural Network architecture including input layers, hidden layers and output layers, according to example embodiments described in the present disclosure.

FIG. 3 is an example illustration of a schematic representation of a process flow for a driver simulation modeling system, according to example embodiments described in the present disclosure.

FIG. 4 is an example illustration of a computing component that includes one or more hardware processors and machine-readable storage media storing a set of machine-readable/machine-executable instructions that, when executed, cause the one or more hardware processors to perform an illustrative method of determining optimal driving parameters and functions, according to example embodiments described in the present disclosure.

FIG. 5 is an example illustration of a computing component that may be used to implement various features of embodiments described in the present disclosure.

The figures are not exhaustive and do not limit the present disclosure to the precise form disclosed.

### DETAILED DESCRIPTION

As described above, the parameters and the method of driving a vehicle to achieve vehicle setup optimization for racing may be difficult to determine for different drivers. Each driver may have varying subjective views regarding the desired performance of a vehicle in accordance with different vehicle setups, different race conditions, or a combination(s) thereof. For example, the “line” a driver may take at a particular section of a racetrack may necessitate a particular vehicle configuration in order for the driver to traverse that line in the manner desired. The subjective view of a driver may also be unique between different drivers according to driver characteristics, experience and preference for operating a vehicle. Determining parameters and methods of driving a vehicle to achieve vehicle setup optimization for racing based on the subjective views, characteristics and preference of a driver cannot be easily or directly modeled through conventional simulation techniques.

Embodiments of the technology disclosed herein provide systems and methods configured to evaluate different vehicle configurations in simulation through deriving a driving model that can accurately account for driver preferences, environment settings and changes in vehicle setup without using independent models. In particular, the embodiments disclosed herein are configured to determine optimal vehicle setup parameters, higher level goals and lower level functions to be implemented on a vehicle during a race. Vehicle setup parameters may include vehicle characteristics such as mechanical and electrical settings and components of a vehicle. Mechanical settings of a vehicle may include physical parameters of the vehicle, such as the design of the vehicle's structure (chassis, aerodynamic features, etc.), the materials used for the vehicle's structure, physical components of the vehicle, etc. Electrical settings of a vehicle may include the electrical wiring, electrical components, interface between the electrical components, etc.

Higher level goals may include intermediate goals to be accomplished with a vehicle while the vehicle is in motion on a racetrack, including selecting optimum apex points for different corners, and identifying the fastest braking and downshifting points for corners and the optimum acceleration points on a particular racetrack. Lower level functions may include actions to be performed with the vehicle while on the racetrack in order to meet or achieve in the intermediate goals. Functions may include braking and handling techniques that may be performed with a vehicle while the vehicle is in motion on the racetrack, such as steering the vehicle, applying the brakes, applying more gas to accelerate, applying less gas to decelerate, changing gears, etc. Functions may also include methods of how to perform actions, such as the amount of steering, the amount of braking, the amount of acceleration, the number of gear to use, etc. that may influence the way that a vehicle maneuvers. Functions may also include performing adjustments to physical parameters of the vehicle while the vehicle is in motion, such as making adjustments to the sway-bar, anti-roll bar, weight jacker, brake bias adjuster, etc. Functions may further include performing adjustments to electronic parameters and settings of the vehicle, such as making adjustments to the traction control setting, Anti-Lock Braking System (ABS) setting, engine and throttle mapping choices, etc. In addition, the driving model is further adapted to set higher level goals that mimic a driver's approach to particular racetracks.

The systems and methods disclosed herein may be implemented with any of a number of different vehicles and vehicle types. For example, the systems and methods disclosed herein may be used with race cars, automobiles, trucks, motorcycles, recreational vehicles and other like on- or off-road vehicles. In addition, the principals disclosed herein may also extend to other vehicle types as well. The systems and methods for virtual test driving can be implemented in other types of vehicle including gasoline- or diesel-powered vehicles, fuel-cell vehicles, electric vehicles, or other vehicles.

Embodiments disclosed herein provide for generating a machine-learning (ML) driving model using a hierarchical reinforcement learning approach that permits training across different vehicle configurations (such as vehicle setup parameters), and variables (such as driver preference and environment settings), in parallel. This permits the ML driving model to tailor lower level functions of a vehicle to achieve higher level goals, and the ML driving model permits driving simulations to more accurately determine optimal vehicle setups, optimal higher level goals and optimal lower level functions to achieve the optimal driving performance in a race according to specific variables or factors that are relevant to a particular race. Embodiments disclosed herein may ingest a plurality of training data, including vehicle setup data, driver data, and environment data, and may apply the training data to ML control algorithms, which outputs determinations of higher level goals and lower level functions to achieve the higher level goals according to the training data.

The training data may include characteristics regarding a race, such as vehicle setup data, driver data and environment data. The vehicle setup data may include mechanical and electrical settings of a vehicle. Mechanical settings of a vehicle may include physical parameters of the vehicle, such as the design of the vehicle's structure, the materials used for the vehicle's structure, physical components of the vehicle, etc. Electrical settings of a vehicle may include the electrical wiring, electrical components, interface between the electrical components, etc. The driver data may include one or more driver performance characteristics. Various driver performance characteristics may be associated with a driver based on the driver's preferences with driving. The driver data may include information of various drivers, with each driver's individual data having a set of driver performance characteristics associated with that particular driver. The environment data may include information associated with the environment of a race, such as the layout of a racetrack, conditions of the pavements of the racetrack, weather settings, number of vehicles in the race, etc. The environment data may include the layouts of multiple racetracks and all of the different variations of weather, pavement conditions, etc. that may occur during a race. The characteristics regarding a race may include every possible variable and combination of variables that may be available and present during any given race.

A driving model may be trained from the ML control algorithms based on the training data, the determined higher level goals and determined lower level functions. A plurality of driving models may be trained according to different sets of training data. For example, a first driving model may be trained that is based on training data associated with a first driver and a second driving model may be trained that is based on training data associated with a second driver.

Particular race characteristics may be received and the race characteristics may be indicative of characteristics of a particular race. The race characteristics may include information of conditions, configurations, and variables that are the characteristics specific to the particular race. The race characteristics may include a first vehicle setup, a first driver data or first environment data. The first vehicle setup may include particular mechanical and electrical settings that are present in a vehicle. The first driver data may include driver preferences for a particular driver that may be driving the vehicle during a race. The first environment data may include information associated to a particular racetrack that a race may be taking place, particular weather settings based on the weather on the day of the race, the particular road conditions for the particular racetrack, etc.

Based on the race characteristics that are received, a set of higher level goals and lower level functions may be derived from the ML driving model. The derived set of higher level goals and lower level functions may be applied to a simulation engine to perform driving simulation. Based on the obtained race characteristics and the performed driving simulations, results comprising an optimal vehicle setup, optimal goals and optimal functions may be generated. The optimal vehicle setup may include vehicle parameters to be implemented on a vehicle to optimize performance of the vehicle during a race. The optimal higher level goals may include intermediate goals to be achieved using a vehicle to optimize performance of the vehicle during a race. The lower level functions may include actions to be implemented by a vehicle to achieve the higher level goals to optimize performance of the vehicle during a race. For example, an optimal higher level goal for a particular race may include making a first turn of a racetrack at the apex point with the fastest time and least deceleration. Lower level functions may be determined that, when performed by a driver, would achieve turning at the first turn at the apex point with the fastest time and least deceleration. Such lower level functions may include making the first turn at the apex point at a particular angle and at a particular speed, and changing gears to accelerate at a particular time after hitting the apex point.

The results may be displayed on a Graphical User Interface (GUI). The results may also be used to perform a simulation to demonstrate how the results may be achieved. The simulation of the results may be displayed on the GUI. An adaptive controller may be generated that adapts to changes in the race characteristics. The changes in the race characteristics may be received and a second set of higher level goals and a second set of lower level functions of the vehicle may be derived based on the changes in the race characteristics. The second set of higher level goals and the second set of lower level functions may be derived from the driving model. One or more new simulations may be performed of the second set of higher level goals and the second set of lower level functions. Second results may be generated based on the changes in the race characteristics, the driving model and the one or more new simulations. The second results may be displayed on the GUI.

Conventional systems are unable to perform various driving simulations in parallel and determine optimum higher level goals and lower level functions to achieve optimum driving performance based on various vehicle setups, driver preferences and/or environmental settings, with such higher level goals and lower level functions emulating intermediate goals that an individual driver would make when racing. Generally, determining optimum higher level goals and lower level functions to achieve optimum driving performance for each combination of parameters of vehicle setup, driver preference and environmental setting would have to be determined through a trial by error approach through real-world testing. That is, a vehicle would be configured with a vehicle setup and a driver would drive the vehicle around the track and then the driver would be asked a series of questions (e.g., provide a subjective opinion on the operation and/or feel of the vehicle) to obtain the driver's preference. The vehicle setup would then be tweaked, and the process repeated for each vehicle setup and for various different environmental settings with the same driver performing the real-world testing. This process would have to be done for each driver for each combination of vehicle setup and environmental settings. Another approach involves determining a drivability score for a race car and modeling a driver from the drivability score. In yet another approach, a historical driver was provided to a computer performed racing simulation and real-world, on-track racing performance could be predicted from the racing simulation. Another example approach allowed for simulation of different vehicle setups using different vehicle setup criteria and a simulator conveys how each vehicle setups can feel, drive, sound, and look to a driver, along with determining performance characteristics of a race. However, none of these approaches provided for determining optimum higher level goals and lower level functions to achieve optimum driving performance with respect to different vehicle setups, driver preferences, and environmental settings, that could then be used to optimize driving performance on a racetrack.

The technology disclosed herein address the above-described short comings of conventional systems by modeling driver preferences, environment settings and changes in vehicle setup using ML control algorithms to determine higher level goals and lower level functions. The optimal driving performance on a racetrack may be achieved by determining optimal vehicle setup parameters, optimal higher level goals and optimal lower level functions based on specific vehicle configurations, driving preferences and/or environment settings. Once the optimal vehicle setup parameters are determined, the optimal vehicle setup parameters may be implemented on a vehicle. Once the optimal higher level goals and optimal lower level functions are determined, a driver may implement the optimal higher level goals and optimal lower level functions for on-track testing to determine if the optimal driving performance may be achieved in the real-world. By using the optimal vehicle setup parameters, optimal higher level goals and optimal lower level functions, on-track testing can be optimized for efficiency and verification of driving simulation performance results. Accurate determination of optimal vehicle setup parameters, optimal higher level goals and optimal lower level functions allows embodiments described herein to optimize driving performance on a racetrack with minimum expenditures.

Machine learning on a number of vehicle setups for varying driver preferences and racetrack conditions allows for the determination of higher level goals and lower level functions to improve over time, leading to faster and improved simulations and prediction on driving performance feedback. A result of the accurate prediction on driving performance feedback may efficiently determine optimal vehicle setup parameters, optimal higher level goals and optimal lower level functions to be implemented on-track to balance the speed, handling and overall performance of a vehicle by a driver during a race to achieve optimal results in driving performance on a racetrack. The prediction on driving performance feedback may aid in generation of a racing strategy (such as apex points, braking points, acceleration points, braking and handling techniques, and adjustments to parameters on the vehicle) that may provide a relatively high chance of success in achieving the best driving performance during a race and improve chances of success in winning races.

Embodiments disclosed herein may provide for use of various racing strategies and iterative tuning of vehicle setups based on changes in weather settings, driver preferences and other relevant contextual factors. For example, early in a race or race session, an optimal racing strategy could be determined based on a hot with no winds weather conditions, an aggressive selection of driver preferences and an aggressive selection of vehicle characteristics. Meanwhile, as the race or end of race session approaches, an optimal racing strategy could be determined based on a colder and windy weather conditions, a less aggressive selection of driver preferences and changes in vehicle characteristics. Relevant contextual factors could include, but not limited to, duration of a race or race session, changes in vehicle characteristics throughout a race or race session, and the like.

Accordingly, the technology disclosed herein can improve over the conventional systems by avoiding the need for running explicit simulations of a vehicle setup, driver preference, and environmental settings over a racetrack through real-world testing. Additional improvements are provided by correlating vehicle setups, driver preference and environmental settings to determine higher level goals and lower level functions that accurately reflect goals and actions that race drivers with actual, real-world experience would implement during a race, to generate accurate driving simulations that may be used as a surrogate for professional drivers during vehicle development and tuning processes.

While embodiments of the present disclosure are described in the context of racing, a person of ordinary skill in the art would understand that embodiments could be readily adapted for use in other driving and/or vehicular contexts. For example, consumer-driven vehicles could be tweaked, adjusted, modified, etc., during design, manufacturing, and/or repair stages based on similar vehicle setup, driver preference and environmental setting parameters to provide optimal driving performance. ML driving models may be utilized to further determine higher level goals and lower level functions for a consumer driver to follow and perform based on vehicle setup, driver preference and environmental settings. The higher level goals and lower level functions may allow a consumer driver to achieve optimum driving performance of a consumer-driver vehicle. This may ultimately improve the driving performance and flow of traffic between consumer-driver vehicles on public roads. Many variations are possible.

It should be noted that the terms “optimize,” “optimal,” “optimum” and the like as used herein can be used to mean making or achieving performance as effective or perfect as possible. However, as one of ordinary skill in the art reading this document will recognize, perfection cannot always be achieved. Accordingly, these terms can also encompass making or achieving performance as good or effective as possible or practical under the given circumstances, or making or achieving performance better than that which can be achieved with other settings or parameters.

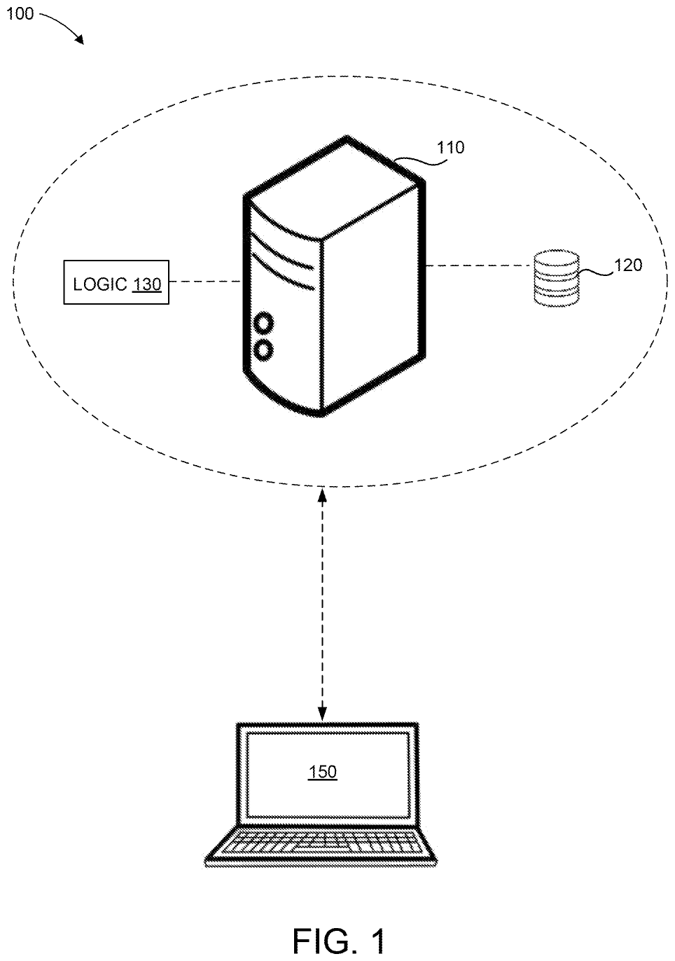

FIG. 1 illustrates an example of a computing system 100 which may be internal or otherwise associated within a device 150. In some embodiments, the computing system 100 may be a ML pipeline and model. In some examples, the device 150 may be a computing device, such as a desktop computer, a laptop, a mobile phone, a tablet device, an Internet of Things (IoT) device, etc. The device 150 may input data into computing component 110. The computing component 110 may perform one or more available assessments on the input data to generate outputs, such as higher level goals and lower level functions to achieve the higher level goals. The device 150 may further display the outputs on a screen of device 150. The screen of device 150 may display the outputs as a two dimensional (2D) dataset and/or table showing the various outputs predicted by a ML driving model based on various input data, such as vehicle setup, driver preference and environment settings. The screen of device 150 may display the outputs as a visual simulation of race car performance according to the input data. The screen of device 150 may display outputs of results of optimum vehicle setup, optimum higher level goals and optimum lower level functions according to the one or more performed assessments. The computing component 110 may include one or more hardware processors and logic 130 that implements instructions to carry out the functions of the computing component 110, for example, receiving training data associated with configurations of a vehicle, generating higher level goals according to the training data, determining lower level functions of the vehicle to achieve the higher level goals based on control algorithms, training a driving model based on the training data, the higher level goals and the lower level functions and the simulation, receiving race characteristics indicative of characteristics of a first race, deriving a first set of higher level goals and a first set of lower level functions of the vehicle from the driving model based on the race characteristics, performing one or more simulations of the first set of higher level goals and the first set of lower level functions based on the race characteristics, and generating results comprising an optimal vehicle setup, optimal higher level goals and optimal lower level functions according to the one or more simulations. The computing component 110 may store, in a database 120, details regarding scenarios or conditions in which some algorithms, image datasets, and assessments are performed and used to determine optimal vehicle setup, optimal higher level goals and optimal lower level functions according to the input data. Some of the scenarios or conditions will be illustrated in the subsequent FIGS.

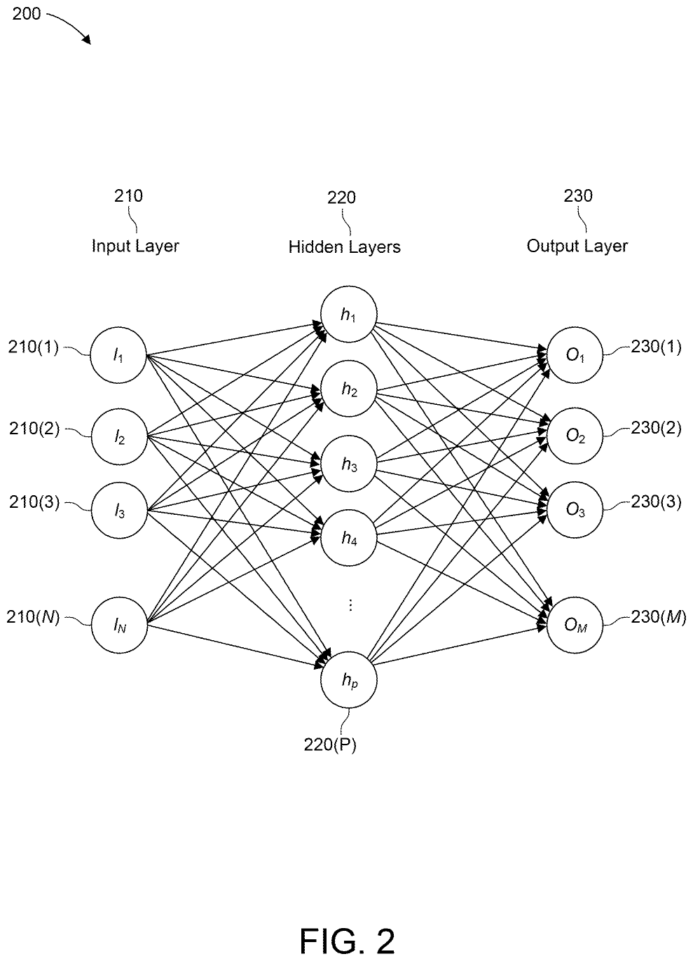

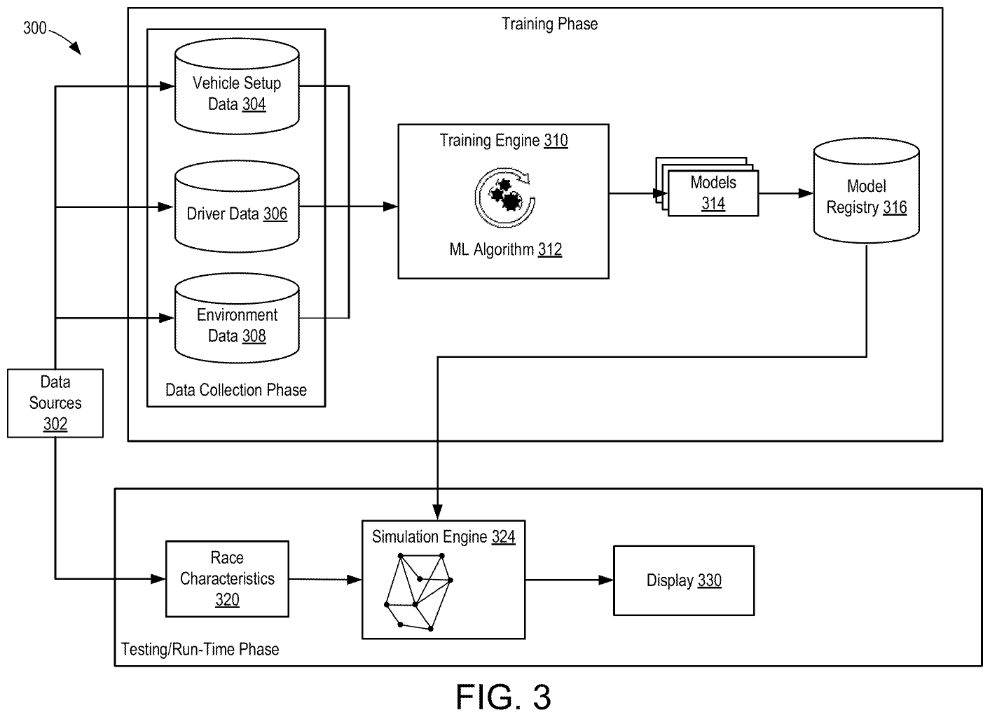

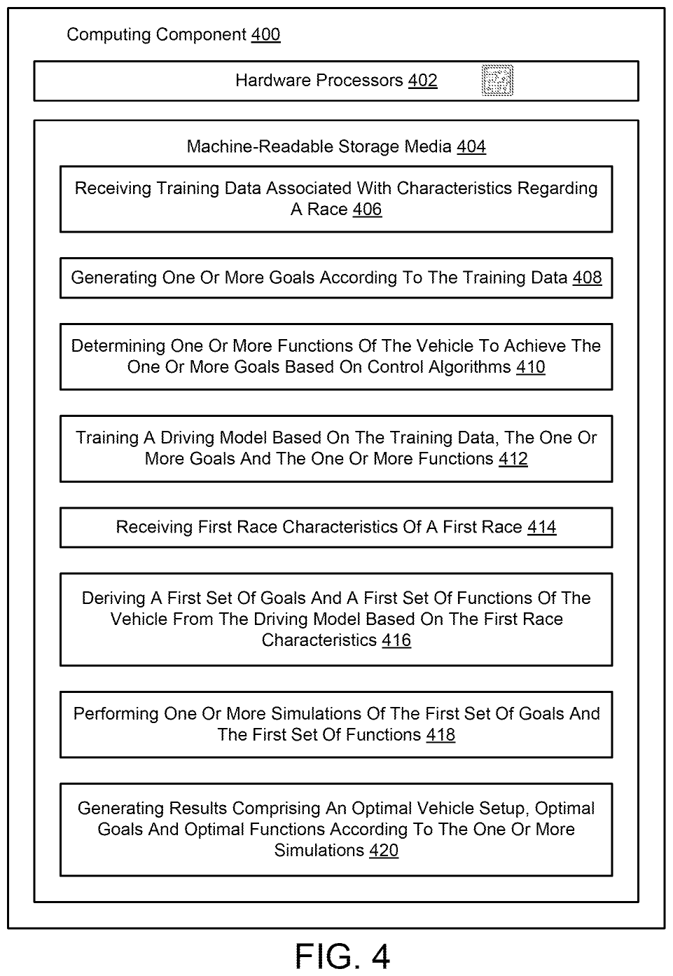

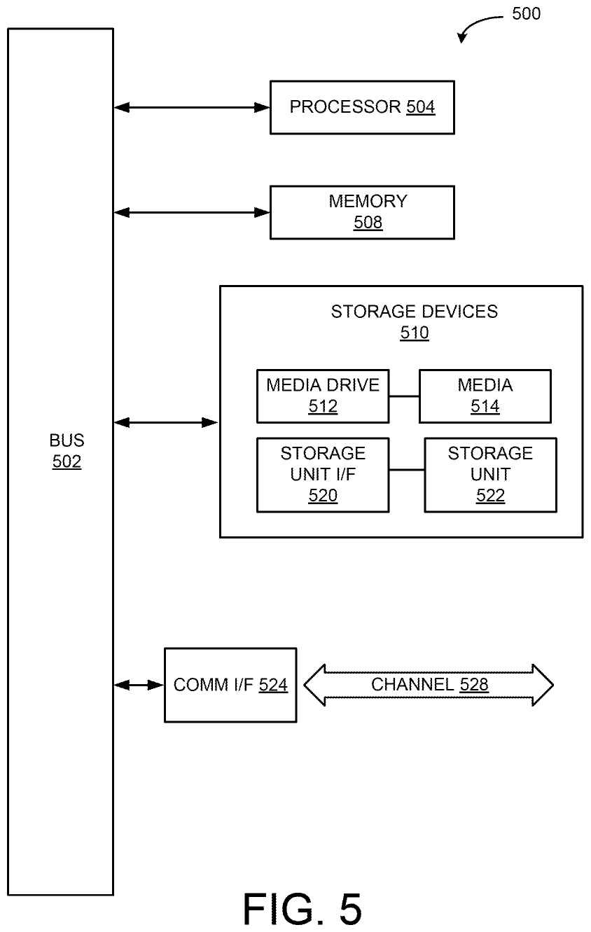

FIG. 2 illustrates an example schematic of a Neural Network (NN) architecture. NNs, such as NN 200, typically consist of an input neuron layer 210, hidden neuron layers 220, an output neuron layer 230, and synaptic interconnections, which can be abstracted by arbitrary weight matrices. NNs are a subset of machine learning and may rely on training data to learn and improve their accuracy over time. As the NN improves and fine-tunes learning algorithms for accuracy, data may be classified and clustered at a higher velocity. Tasks, such as driving simulation modeling, may take minutes versus hours when compared to manual test driving. A NN may consist of more than three layers and the more hidden neuron layers present in an NN, the greater the performance and accuracy that the NN can achieve. In some embodiments, the NN 200 can be executed, for example, by the computing component 110 of FIG. 1. In other embodiments, the NN 200 may be implemented as the computing component 110 of FIG. 1. The computing component 110 may be, for example, the process 300 of FIG. 3, the process 400 of FIG. 4 and the computing component 500 of FIG. 5. The computing component 110 may include a server.

As alluded to above, recommending an optimal vehicle setup, optimal higher level goals and optimal lower level functions can be accomplished over the course of a data collection phase, a training phase, and a testing/run-time phase. FIG. 3 is a schematic representation of an example process flow for an optimal driving performance recommendation system 300 embodying these phases separated into training phase and run-time phase. System 300 may be implemented, for example, as the computing component 110 of FIG. 1, the process 400 of FIG. 4 and the computing component 500 of FIG. 5.

Optimal driving performance recommendation system 300 may be configured to assist a racing team in determining an optimal vehicle setup, optimal higher level goals and optimal lower level functions to be implemented for a race. The optimal vehicle setup may be an initial vehicle setup or a later progressive setup. Optimal driving performance recommendation system 300 may function to determine higher level goals according to different combinations of vehicle setups and other factors, such as the driver preferences and environmental settings, including the racetrack layout. Optimal driving performance recommendation system 300 may then use the higher level goals to determine lower level functions that may be performed to accomplish the higher level goals for each combination of vehicle setups and other factors. Optimal driving performance recommendation system 300 may further perform simulations of the higher level goals and lower level functions to determine an optimal vehicle setup, optimal higher level goals and optimal lower level function to achieve optimum driving performance based on particular conditions and variables of a race. The particular conditions, configurations and variables that make up the characteristics of a race may be considered as race characteristics and the race characteristics may change for each race and throughout the duration of a race. The system 300 may determine different optimal vehicle setups, optimal higher level goals and optimal lower level functions to be implemented to optimize driving performance for a race for different sets of race characteristics.

In the data collection phase, training data is obtained from various data sources 302. For example, training data may include information defining one or more vehicle setups (referred to herein as vehicle setup data 304). Vehicle setup data 304 can be provided as vehicle setup parameters that collectively define a vehicle's configuration. Vehicle setup parameters may include mechanical configuration settings of a vehicle, such as, but not limited to, engine operating parameters, handling/suspension parameters, transmission parameters, fuel system parameters, braking parameters, exhaust parameters, etc., and electrical configuration settings, such as, but not limited to, battery parameters, motor parameters, lighting system parameters, ignition system parameters, controls system parameters, etc. These vehicle setup parameters may be varied from one vehicle setup to the next. In an illustrative example, a first vehicle setup may include operating parameters, such as, GT 3, front shock to 800 Nm, rear camber at −1.5 degrees, among others. A second vehicle setup may include the same parameters except rear camber set to −1 degree. Numerous vehicle setups are possible. The vehicle setup data 304 can be input, for example, into the computing component 110 from device 150. The vehicle setup data 304 can also be stored in database 120 for the computing component 110 to retrieve.

Training data may also include driver data 306, such as, but not limited to, preferences, characteristics, driving methods, driving performance feedback, etc., that are associated with a driver. For example, driver data 306 may include subjective driving performance feedback of a driver in the way the driver performs when driving on a racetrack. The driver data 306 may also include subjective driving methods that the driver uses when driving on a racetrack, such as, how and when the driver accelerates, brakes, steers, etc. during the course of the racetrack. The driver data 306 may also include subjective preferences of the driver in the choice of vehicle operating parameters of a vehicle. The driver data 306 may also include subjective characteristics of the driver, such as, the personality and attitude of the driver when driving on a racetrack. Numerous driver data are possible and the driver data may include data associated with various drivers. In an illustrative example, driver data of a first driver may include an aggressive characteristic while driving on a racetrack, with aggressive preferences in the vehicle operating parameters and an aggressive driving method of high acceleration with minimum breaking. The driver data of a second driver may include a neutral approach to driving on a racetrack, with characteristics that are more cautious, balanced preferences in the vehicle operating parameter with regards to acceleration, braking, steering and handling, and a fluent driving method where the second driver changes from high to low acceleration and low to high braking based on different areas of the racetrack. The driver data 306 can be input, for example, into the computing component 110 from device 150. The driver data 306 can also be stored in database 120 for the computing component 110 to retrieve.

Training data may also include environment data 308, such as, but not limited to, racetrack layouts, weather settings, pit crew setups, race durations, etc., that are associated with a race. For example, environment data 308 may include the layout of a racetrack, including the location of every turn, every straightaway, pit stop, audiences, etc. The environment data 308 may also include the type and degree of weather that may be present during a race, such as, sunny, windy, rainy, high/hot temperature, low/cold temperature, etc. The environment data 308 may also include the condition of the pavement of a racetrack that may be present during a race, such as, the pavement being dry and hot, wet and slippery, uneven with excessive gravel, etc. The environment data 308 may also include the pit crew setup, such as, the individuals used as the pit crew during a race. The environment data may also include the duration of a race, such as, the number of laps, the number of days, time, etc. Numerous combinations of environment data are possible. In an illustrative example, environment data of a first race may include a first racetrack that has a duration of 2 days, in a location with temperatures ranging from 30 degrees Fahrenheit to 110 degrees Fahrenheit throughout the course of a day. A second race may include a second racetrack that has a duration of 10 laps, in a location with temperatures around 60 degrees Fahrenheit and high winds and rain in the midday. The environment data 308 can be input, for example, into the computing component 110 from device 150. The environment data 308 can also be stored in database 120 for the computing component 110 to retrieve.

In the training phase, training data is retrieved by training engine 310 from repositories, such as vehicle setup data 304, driver data 306 and environment data 308. The training data is applied to a ML algorithm 312 to generate a ML driving model 314 for each combination of vehicle setup data, driver data and environment data. For example, training data can be divided into sets according to each vehicle setup, each driver, and/or each racetrack. The training engine 310 then applies each set of training data associated with a respective vehicle setup, driver and/or racetrack to the ML algorithm 312 to generate a ML driving model 314 for that vehicle setup, driver and/or racetrack. A plurality of ML driving models 314 may be trained according to different sets of training data. For example, a first driving model may be trained that is based on training data associated with a first driver and a second driving model may be trained that is based on training data associated with a second driver. The ML algorithm 312 may process each set of training data to determine a set of higher level goals that may be accomplished throughout the course of a race according to the applied set of training data. Higher level goals may include intermediate goals to be accomplished with a vehicle while the vehicle is in motion on a racetrack, including selecting optimum apex points for different corners, and identifying the optimum braking, downshifting and acceleration points a particular racetrack. In addition, the ML algorithm 312 may further generate a set higher level goals that mimic a driver's approach to a particular racetrack.

The ML algorithm 312 may further process the higher level goals for a particular set of training data to determine a set of lower level functions that may be implemented with a vehicle during a race to achieve the higher level goals. Lower level functions may include actions to be performed with the vehicle while on the racetrack. Functions may include braking and handling techniques that may be performed with a vehicle while the vehicle is in motion on the racetrack, such as steering the vehicle, applying the brakes, applying more gas to accelerate, applying less gas to decelerate, changing gears, etc. Functions may also include methods of how to perform actions, such as the amount of steering, the amount of braking, the amount of acceleration, the number of gear to use, etc. that may influence the way that a vehicle maneuvers. Functions may also include performing adjustments to physical parameters of the vehicle while the vehicle is in motion, such as making adjustments to the sway-bar, anti-roll bar, weight jacker, brake biases adjuster, etc. Functions may further include performing adjustments to electronic parameters and settings of the vehicle, such as making adjustments to the traction control setting, Anti-Lock Braking System (ABS) setting, engine and throttle mapping choices, etc. Each ML driving model 314 may include the set of higher level goals and associated lower level functions with the applied set of training data.

In one example, a first set of higher level goals may be based on a first set of vehicle setup data, driver data and environment data, such as using a drift racecar with a driver A on wet and slippery road conditions for racetrack G. The training engine 310, using ML algorithm 312, may determine that one higher level goal of the first set of higher level goals may be that at a first turn of the racetrack G, the apex point should be at point X. In another example, a second set of higher level goals may be based on a second set of vehicle setup data, driver data and environment data, such as using a rally racecar with a driver B on hot and dry road conditions for racetrack H. The training engine 310, using ML algorithm 312, may determine that one higher level goal of a second set of higher level goals may be that at a first turn of the racetrack H, the apex point should be at point Y. The determination of a higher level goal in the apex point location is to achieve the best results in terms of timing, handling, etc. for that first turn of the particular racetrack. The lower level functions that are then determined are actions that may be performed with the vehicle to achieve the respective higher level goal(s). In one example, to accomplish the higher level goal of the apex point at point X based on the first set of vehicle setup data, the training engine 310, using ML algorithm 312, may determine that a lower level function of the vehicle may include handling the turn for apex point X at a particular time and angle, the speed to take the turn may be a certain amount, the time in which to brake before the apex point may be at a certain time/location on the racetrack, etc. A lower level function may also include having a driver make changes to mechanical or electrical settings of the vehicle such as adjusting the brake biases adjuster, the sway-bar, traction control settings, etc.

ML can refer to methods that, through the use of algorithms, are able to automatically extract intelligence or rules from training data sets and capture the same in informative models. In turn, those models are capable of making predictions based on patterns or inferences gleaned from subsequent data input into a trained model. According to implementations of the disclosed technology, the ML algorithm 312 comprises, among other aspects, algorithms implementing a Gaussian process and the like. The ML algorithms 312 disclosed herein may be supervised and/or unsupervised depending on the implementation. The ML algorithms 312 may be based on a hierarchical reinforcement learning approach that more closely mirrors the adaptation process described by professional human drivers. The ML algorithms 312 may emulate the observed characteristics of human drivers allowing the system to better model actual driving conditions and mimic a human driver's actions and performance. Thus, the ML driving models 314 may include higher level goals and lower level functions that emulate goals and actions that a human driver may determine and implement in a real-world experience.

In an illustrative example, the ML driving models 314 can be trained according to training parameters, which may be used to constrain the training. Training parameters may be set according to relevant contextual factors, such weekend or season schedules, team standings both during a single weekend and throughout the season, and the like. The training parameters may account for the temporally longitudinal nature of vehicle tuning for a race vehicle, such that high risk, high reward vehicle setups can be suggested early on and low risk, low reward setups suggested as race day (or season end) approaches. That is, for example, more deference may be given to a driver's subjective preferences early on over objective performance, or vice versa.

The ML driving models 314 generated by the ML algorithms 312 in training engine 310 may be stored in the model registry 316. The model registry 316 may organize each ML driving model 314 according to one or more of the applied training data, such as the vehicle setup, driver, and/or racetrack. The training phase may be repeated for a number of sets of training data to generate a plurality of ML driving models 314 stored to model registry 316. For example, training data corresponding to a particular racetrack and a particular driver may be applied to the ML algorithm 312 to generate a ML driving model 314 for that respective racetrack and driver. In this way, a unique ML driving model 314 can be created for each racetrack and driver, which can be used to predict the optimal vehicle setup, optimal higher level goals and optimal lower level functions to be implemented. The model registry 316 may be, for example, database 120 of FIG. 1.

In the testing/run-time phase, race characteristics 320 defining conditions, configurations and variables that make up the characteristics of a particular race can be input into a simulation engine 324. The race characteristics 320 may include a first vehicle setup, a first driver data or first environment data. The first vehicle setup may include particular mechanical and electrical settings that are present in a vehicle. The first driver data may include driver preferences for a particular driver that may be driving the vehicle during a race. The first environment data may include information associated to a particular racetrack that a race may be taking place, particular weather settings based on the weather on the day of the race, the particular road conditions for the particular racetrack, etc.

The simulation engine 324 may process and analyze the race characteristics 320 to determine the associated ML driving model 314 to extract from the model registry 316. The simulation engine 324 may use the extracted ML driving model 314 with the inputted race characteristics 320 to derive a set of higher level goals and lower level functions from the ML driving model 314 to perform virtual driving simulations on. Based on the derived race characteristics 320 and the performed virtual driving simulations, the simulation engine 324 may generate results comprising of an optimal vehicle setup, optimal goals and optimal functions. The optimal vehicle setup may include vehicle parameters to be implemented on a vehicle to optimize performance of the vehicle during a race. The optimal higher level goals may include intermediate goals to be achieved using a vehicle to optimize performance of the vehicle during a race. The lower level functions may include actions to be implemented by a vehicle to achieve the higher level goals to optimize performance of the vehicle during a race.

As each ML driving model 314 may be specific to a given vehicle setup, given driver, a given racetrack and/or any other variable specific for a particular race, the generated results of optimal vehicle setup, optimal higher level goals and/or optimal lower level functions may be specific to the specific variable (e.g., true and dependent on the respective vehicle setup, respective driver, and/or respective racetrack). The simulation engine 324 may apply the race characteristics 320 to the associated ML driving model 314 via simulating a race performance of each combination of vehicle setups, higher level goals and lower level functions for the specific race characteristics 320 to determine the performance of a race for each combination. The simulation engine 324 may use the simulations and the race characteristics 320 to then generate results of optimal vehicle setup, optimal goals and optimal functions that may be implemented to achieve optimal driving performance.

The simulation engine 324 may determine the results of the optimal vehicle setup, optimal higher level goals and/or optimal lower level functions based on a tradeoff between object performance metrics and the subjective driver data and environment data. Examples of objective performance metrics include, but are not limited to, lap times around a track, total race time, pit stop frequency, fuel consumption rate, distance between vehicle race line (e.g., path traveled by the vehicle), ideal race line and other vehicles in a race, among others. Each objective performance metrics can be based on real-world experience and knowledge of a vehicle, race, and/or racetrack, according to a vehicle setup and/or through computer simulation on a vehicle setup. In certain cases, there may exist a tradeoff between the objective performance of a vehicle and the subjective preferences of the driver (e.g., a vehicle setup preferred by a driver may not translate to an ideal simulated performance). However, it may be desirable to meet the driver's preferences as a comfortable and subjectively satisfied driver may be able to implement certain higher level goals and lower level functions to drive the vehicle faster and more aggressively, as compared to a case where the preferences are not met. Thus, simulation engine 324 may balance the objective performance metrics with other preferences that may be included in the race characteristics 320 to determine an optimal vehicle setup, optimal higher level goals and optimal lower level functions to be implemented for a particular race.

The simulation engine 324 may analyze the race characteristics 320 by sensitivity analysis techniques. For example, for a given race characteristics 320 with a particular vehicle setup, the impact of each vehicle configuration parameter that makes up the vehicle setup can be analyzed to determine the higher level goals and lower level functions that may achieve the most optimal driving performance. Some possible sensitivity analysis techniques include, but are not limited to, One-Factor-At-A-Time method, derivative-based local methods, regression analysis, variance-based methods, variogram analysis of response surfaces (VARS), screening, scatter plots, and the like.

The simulation engine 324 may send the results to a display 330, such as a Graphical User Interface (GUI), to display the results for viewing. The simulation engine 324 may also use the results to perform a simulation to demonstrate how the results may be achieved. The simulation engine 324 may send the simulation of the results to the display 330 to the displayed for viewing. The results may also include driving performance feedback which may include a summary of the results of a simulated race performance, such as, but not limited to, the time to complete each optimal higher level goal, the likelihood of success in achieving the optimal lower level functions, the time to complete the race, the durability of the vehicle based on the vehicle setup, the vehicle configurations of the optimal vehicle setup, etc. The results displayed by display 330 may then be implemented by in the real-world for real-world testing. The display 330 may be implemented, for example, as the device 150 of FIG. 1.

The optimal driving performance recommendation system 300 may generate an adaptive controller that adapts to changes in the race characteristics 320. Changes in the race characteristics 320 may include changes in the vehicle setup, changes in the driver preferences and/or changes in environment settings, such as changes in the weather, road conditions, and number of laps. The changes in the race characteristics 320 may be received and the simulation engine 324 may derive a second set of higher level goals and a second set of lower level functions of the vehicle from the based on the changes in the race characteristics 320. The second set of higher level goals and the second set of lower level functions may be derived from the driving model 314 stored in model registry 316. The simulation engine 324 may perform one or more new simulations of the second set of higher level goals and the second set of lower level functions. The simulation engine 324 may generate second results based on the changes in the race characteristics 320, the driving model 314 and the one or more new simulations. The simulation engine 324 may send the second results to the display 330 to be displayed for viewing.

An end-user, such as a race engineer in various examples, may interface with the optimal driving performance recommendation system 300, which may provide access via a screen or other graphical user interface (GUI) on a device, such as device 150 of FIG. 1. Device 150 may be provided as one or more of a mobile device, a personal computer, a laptop, a tablet, and any computing device, such as computing component 110 of FIG. 1. End-users may enter inputs into device 150, which computing component 110 may receive from device 150, and computing component 110 may send information to device 150 for presentation via the screen or applicable GUI.

FIG. 4 illustrates an example computing component 400 that includes one or more hardware processors 402 and machine-readable storage media 404 storing a set of machine-readable/machine-executable instructions that, when executed, cause the hardware processor(s) 402 to perform an illustrative method of performing driver simulation modeling and determining optimized vehicle setup, optimized higher level goals and optimized lower level functions. It should be appreciated that there can be additional, fewer, or alternative steps performed in similar or alternative orders, or in parallel, within the scope of the various examples discussed herein unless otherwise stated. The computing component 400 may be implemented as the computing component 110 of FIG. 1, the process 300 of FIG. 3, and process 400 of FIG. 4. FIG. 5 summarizes and further elaborates on some aspects previously described.

At step 406, the hardware processor(s) 402 may execute machine-readable/machine-executable instructions stored in the machine-readable storage media 404 to receive training data associated with characteristics regarding a race. The training data may include vehicle setup data, driver data and environment data. The vehicle setup data may include mechanical and electrical settings of a vehicle. Mechanical settings of a vehicle may include physical parameters of the vehicle, such as the design of the vehicle's structure, the materials used for the vehicle's structure, physical components of the vehicle, etc. Electrical settings of a vehicle may include the electrical wiring, electrical components, interface between the electrical components, etc. The driver data may include one or more driver performance characteristics. Various driver performance characteristics may be associated with a driver based on the driver's preferences with driving. The driver data may include information of various drivers, with each driver's individual data having a set of driver performance characteristics associated with that particular driver. The environment data may include information associated with the environment of a race, such as the layout of a racetrack, conditions of the pavements of the racetrack, weather settings, number of vehicles in the race, etc. The environment data may include the layouts of multiple racetracks and all of the different variations of weather, pavement conditions, etc. that may occur during a race.

At step 408, the hardware processor(s) 402 may execute machine-readable/machine-executable instructions stored in the machine-readable storage media 404 to generate one or more higher level goals according to the training data. The one or more higher level goals may include intermediate goals for a vehicle to accomplish while in motion on a racetrack. The one or more higher level goals may include a selection of apex points for turns and corners of a racetrack, braking points, downshifting points, acceleration points, etc.

At step 410, the hardware processor(s) 402 may execute machine-readable/machine-executable instructions stored in the machine-readable storage media 404 to determine one or more lower level functions of a vehicle to achieve the one or more higher level goals based on control algorithms. The vehicle may include a race car, automobile, truck, motorcycle, recreational vehicle and other like on- or off-road vehicles. The one or more lower level functions may include an action to be performed with the vehicle while in motion on a racetrack. A lower level function may include braking and handling techniques that may be performed on a vehicle while the vehicle is in motion, such as steering the vehicle, applying the brakes, applying more gas to accelerate, applying less gas to decelerate, changing gears, etc. A lower level function may also include performing adjustments to physical parameters of the vehicle while the vehicle is in motion, such as making adjustments to the sway-bar, anti-roll bar, weight jacker, brake bias adjuster, etc. Lower level function may further include performing adjustments to electronic parameters and settings of the vehicle, such as making adjustments to the traction control setting, Anti-Lock Braking System (ABS) setting, engine and throttle mapping choices, etc.

At step 412, the hardware processor(s) 402 may execute machine-readable/machine-executable instructions stored in the machine-readable storage media 404 to train a driving model based on the training data, the one or more higher level goals and the one or more lower level functions. The driving model may be stored in a model registry.

At step 414, the hardware processor(s) 402 may execute machine-readable/machine-executable instructions stored in the machine-readable storage media 404 to receive first race characteristics indicative of characteristics of a first race. The first race characteristics may include information of variables, configurations, and conditions that make up the characteristics specific to a particular race. The first race characteristics may include at least one of a first vehicle setup, a first driver data or a first environment data. The first vehicle setup may be a set of vehicle parameters of mechanical and electrical settings of a vehicle that are being implemented for a particular race. The first driver data may include a set of driver performance characteristics that are being implemented for a particular race. The first environment data may include a set of information associated with the environment being implemented for a particular race.

At step 416, the hardware processor(s) 402 may execute machine-readable/machine-executable instructions stored in the machine-readable storage media 404 to derive a first set of higher level goals and a first set of lower level functions of the vehicle based on the first race characteristics. The first set of higher level goals and the first set of lower level functions may be derived from the driving model.

At step 418, the hardware processor(s) 402 may execute machine-readable/machine-executable instructions stored in the machine-readable storage media 404 to perform one or more simulations of the first set of higher level goals and the first set of lower level functions based on the first race characteristics.

At step 420, the hardware processor(s) 402 may execute machine-readable/machine-executable instructions stored in the machine-readable storage media 404 to generate results comprising an optimal vehicle setup, optimal higher level goals and optimal lower level functions according to the one or more simulations. The optimal vehicle setup may include vehicle parameters to be implemented on a vehicle to optimize performance of the vehicle during a race. The optimal higher level goals may include intermediate goals to be achieved using a vehicle to optimize performance of the vehicle during a race. The lower level functions may include actions to be implemented by a vehicle to achieve the higher level goals to optimize performance of the vehicle during a race. The results may be displayed on a Graphical User Interface (GUI). The results may also be used to perform a simulation to demonstrate how the results may be achieved. The second simulation of the results may be displayed on the GUI.

An adaptive controller may be generated that adapts to changes in the characteristics of a race. The changes in the characteristics of a race may be received and a second set of higher level goals and a second set of lower level functions of the vehicle may be derived based on the changes in the characteristics of the race, i.e. second race characteristics. The second set of higher level goals and the second set of lower level functions may be derived from the driving model. One or more new simulations may be performed of the second set of higher level goals and the second set of lower level functions. Second results may be generated based on the changes in characteristics of the race, the driving model and the one or more new simulations. The second results may be displayed on the GUI.

Subsequently, the hardware processor(s) 402 may receive subsequent training data from the user and repeat the aforementioned steps for each of the subsequent training data received, until training data are no longer being received from the user.

As used herein, the terms circuit and component might describe a given unit of functionality that can be performed in accordance with one or more embodiments of the present application. As used herein, a component might be implemented utilizing any form of hardware, software, or a combination thereof. For example, one or more processors, controllers, ASICs, PLAs, PALs, CPLDs, FPGAs, logical components, software routines or other mechanisms might be implemented to make up a component. Various components described herein may be implemented as discrete components or described functions and features can be shared in part or in total among one or more components. In other words, as would be apparent to one of ordinary skill in the art after reading this description, the various features and functionality described herein may be implemented in any given application. They can be implemented in one or more separate or shared components in various combinations and permutations. Although various features or functional elements may be individually described or claimed as separate components, it should be understood that these features/functionality can be shared among one or more common software and hardware elements. Such a description shall not require or imply that separate hardware or software components are used to implement such features or functionality.

Where components are implemented in whole or in part using software, these software elements can be implemented to operate with a computing or processing component capable of carrying out the functionality described with respect thereto. One such example computing component is shown in FIG. 5. Various embodiments are described in terms of this example—computing component 500. After reading this description, it will become apparent to a person skilled in the relevant art how to implement the application using other computing components or architectures.

Referring now to FIG. 5, computing component 500 may represent, for example, computing or processing capabilities found within a self-adjusting display, desktop, laptop, notebook, and tablet computers. They may be found in hand-held computing devices (tablets, PDA's, smart phones, cell phones, palmtops, etc.). They may be found in workstations or other devices with displays, servers, or any other type of special-purpose or general-purpose computing devices as may be desirable or appropriate for a given application or environment. Computing component 500 might also represent computing capabilities embedded within or otherwise available to a given device. For example, a computing component might be found in other electronic devices such as, for example, portable computing devices, and other electronic devices that might include some form of processing capability.

Computing component 500 might include, for example, one or more processors, controllers, control components, or other processing devices. This can include a processor, and/or any one or more of the components making up device 150 of FIG. 1 and optimal driving performance recommendation system 300 of FIG. 3. Processor 504 might be implemented using a general-purpose or special-purpose processing engine such as, for example, a microprocessor, controller, or other control logic. Processor 504 may be connected to a bus 502. However, any communication medium can be used to facilitate interaction with other components of computing component 500 or to communicate externally.

Computing component 500 might also include one or more memory components, simply referred to herein as main memory 508. For example, random access memory (RAM) or other dynamic memory, might be used for storing information and instructions to be executed by processor 504. Main memory 508 might also be used for storing temporary variables or other intermediate information during execution of instructions to be executed by processor 504. Computing component 500 might likewise include a read only memory (“ROM”) or other static storage device coupled to bus 502 for storing static information and instructions for processor 504.

The computing component 500 might also include one or more various forms of information storage mechanism 510, which might include, for example, a media drive 512 and a storage unit interface 520. The media drive 512 might include a drive or other mechanism to support fixed or removable storage media 514. For example, a hard disk drive, a solid-state drive, a magnetic tape drive, an optical drive, a compact disc (CD) or digital video disc (DVD) drive (R or RW), or other removable or fixed media drive might be provided. Storage media 514 might include, for example, a hard disk, an integrated circuit assembly, magnetic tape, cartridge, optical disk, a CD or DVD. Storage media 514 may be any other fixed or removable medium that is read by, written to or accessed by media drive 512. As these examples illustrate, the storage media 514 can include a computer usable storage medium having stored therein computer software or data.

In alternative embodiments, information storage mechanism 510 might include other similar instrumentalities for allowing computer programs or other instructions or data to be loaded into computing component 500. Such instrumentalities might include, for example, a fixed or removable storage unit 522 and an interface 520. Examples of such storage units 522 and interfaces 520 can include a program cartridge and cartridge interface, a removable memory (for example, a flash memory or other removable memory component) and memory slot. Other examples may include a PCMCIA slot and card, and other fixed or removable storage units 522 and interfaces 520 that allow software and data to be transferred from storage unit 522 to computing component 500.

Computing component 500 might also include a communications interface 524. Communications interface 524 might be used to allow software and data to be transferred between computing component 500 and external devices. Examples of communications interface 524 might include a modem or soft modem, a network interface (such as Ethernet, network interface card, IEEE 802.XX or other interface). Other examples include a communications port (such as for example, a USB port, IR port, RS232 port Bluetooth® interface, or other port), or other communications interface. Software/data transferred via communications interface 524 may be carried on signals, which can be electronic, electromagnetic (which includes optical) or other signals capable of being exchanged by a given communications interface 524. These signals might be provided to communications interface 524 via a channel 528. Channel 528 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media. Such media may be, e.g., memory 508, storage unit 520, media 514, and channel 528. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing component 500 to perform features or functions of the present application as discussed herein.

It should be understood that the various features, aspects and functionality described in one or more of the individual embodiments are not limited in their applicability to the particular embodiment with which they are described. Instead, they can be applied, alone or in various combinations, to one or more other embodiments, whether or not such embodiments are described and whether or not such features are presented as being a part of a described embodiment. Thus, the breadth and scope of the present application should not be limited by any of the above-described exemplary embodiments.

Terms and phrases used in this document, and variations thereof, unless otherwise expressly stated, should be construed as open ended as opposed to limiting. As examples of the foregoing, the term “including” should be read as meaning “including, without limitation” or the like. The term “example” is used to provide exemplary instances of the item in discussion, not an exhaustive or limiting list thereof. The terms “a” or “an” should be read as meaning “at least one,” “one or more” or the like; and adjectives such as “conventional,” “traditional,” “normal,” “standard,” “known.” Terms of similar meaning should not be construed as limiting the item described to a given time period or to an item available as of a given time. Instead, they should be read to encompass conventional, traditional, normal, or standard technologies that may be available or known now or at any time in the future. Where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “component” does not imply that the aspects or functionality described or claimed as part of the component are all configured in a common package. Indeed, any or all of the various aspects of a component, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A computing system for virtual test driving using a hierarchical reinforcement learning approach comprising:
one or more processors; and
memory coupled to the one or more processors to store instructions, which when executed by the one or more processors, cause the one or more processors to perform operations, the operations comprising:
receiving training data associated with characteristics regarding a race;
generating one or more goals according to the training data;
determining one or more functions of a vehicle to achieve the one or more goals based on control algorithms;
training a driving model based on the training data, the one or more goals and the one or more functions;
performing one or more simulations of a set of goals and a set of functions derived from the driving model based on first race characteristics; and
generating results comprising an optimal vehicle setup, optimal goals and optimal functions according to the one or more simulations.

2. The computing system of claim 1, wherein the training data comprises vehicle setup data, driver data and environment data.

3. The computing system of claim 1, wherein the vehicle is a race car.

4. The computing system of claim 2, wherein the vehicle setup data comprises a mechanical and electrical setting of the vehicle.

5. The computing system of claim 2, wherein the driver data comprises a driver performance characteristic.

6. The computing system of claim 2, wherein the environment data comprises a racetrack layout, conditions of a racetrack and weather setting.

7. The computing system of claim 1, wherein the one or more goals comprises a selection of an apex point, a braking point and an acceleration point.

8. The computing system of claim 1, wherein the one or more functions comprises an action to be performed with the vehicle while the vehicle is in motion.

9. The computing system of claim 1, wherein the first race characteristics comprise at least one of a first vehicle setup, a first driver data or a first environment data.

10. The computing system of claim 1, wherein the operations further comprise displaying the results on a Graphical User Interface (GUI).

11. The computing system of claim 1, wherein the operations further comprise:
performing a second simulation of the results; and
displaying the second simulation of the results on a GUI.

12. The computing system of claim 1, wherein the operations further comprise:
generating an adaptive controller that adapts to changes in characteristics of the race;
generating second results comprising a second optimal vehicle setup, second optimal goals and second optimal functions according to the driving model and second race characteristics; and
displaying the second results on a GUI.

13. A method for virtual test driving using a hierarchical reinforcement learning approach, the method comprising:
receiving training data associated with characteristics regarding a race;
generating one or more goals according to the training data;
determining one or more functions of a vehicle to achieve the one or more goals based on control algorithms;
training a driving model based on the training data, the one or more goals and the one or more functions;
performing one or more simulations of a set of goals and a set of functions derived from the driving model based on first race characteristics; and
generating results comprising an optimal vehicle setup, optimal goals and optimal functions according to the one or more simulations.

14. The method of claim 13, wherein the training data comprises vehicle setup data, driver data and environment data.

15. The method of claim 14, wherein the vehicle setup data comprises a mechanical and electrical setting of the vehicle.

16. The method of claim 14, wherein the driver data comprises a driver performance characteristic.

17. The method of claim 14, wherein the environment data comprises a racetrack layout, conditions of a racetrack and weather setting.

18. The method of claim 13, wherein the one or more functions comprises an action to be performed with the vehicle while the vehicle is in motion.

19. The method of claim 13, further comprising:
displaying the results on a Graphical User Interface (GUI);
performing a second simulation of the results; and
displaying the second simulation of the results on the GUI.

20. A non-transitory machine-readable medium having instructions stored therein, which when executed by a processor, cause the processor to perform operations, the operations comprising:
receiving training data associated with characteristics regarding a race;
generating one or more goals according to the training data;
determining one or more functions of a vehicle to achieve the one or more goals based on control algorithms;
training a driving model based on the training data, the one or more goals and the one or more functions;
performing one or more simulations of a set of goals and a set of functions based on first race characteristics; and
generating results comprising an optimal vehicle setup, optimal goals and optimal functions according to the one or more simulations.
